(19) United States
(12) Patent Application Publication
(10) Pub. No.: US 2016/0146434 A1
(43) Pub. Date: May 26, 2016

(54) CONVERSION ELEMENT INCLUDING A SEPARATING STRUCTURE

(71) Applicant: OSRAM OPTO SEMICONDUCTORS GMBH, Regensburg (DE)

(72) Inventors: Wolfgang Mönch, Pentling (DE); Frank Singer, Regenstauf (DE)

(21) Appl. No.: 14/902,995

(22) PCT Filed: Jul. 3, 2014
(86) PCT No.: PCT/EP2014/064226

§ 371 Date: Jan. 5, 2016

(30) Foreign Application Priority Data
Jul. 9, 2013 (DE) 10 2013 107 227.5

(51) Int. Cl. F21V 9/16; H01S 5/00; F21S 8/10

(52) U.S. Cl. CPC F21V 9/16; F21S 48/1225; H01S 5/005

(57) ABSTRACT

A conversion element includes a separating structure and a multiplicity of conversion regions, wherein each conversion region is at least partly enclosed by a part of the separating structure, and each conversion region converts electromagnetic primary radiation at least partly into a secondary radiation having a longer wavelength.

### TECHNICAL FIELD

This disclosure relates to a conversion element comprising a separating structure and a method of producing same.

### BACKGROUND

In lighting systems comprising a multiplicity of semiconductor chips or pixels, in particular in light emitting diode (LED) headlights for adaptive automotive front lighting, crosstalk between the semiconductor chips or pixels can occur. In these systems, a radiation conversion typically takes place, this being brought about either by an integral converter lamina that covers all the semiconductor chips or pixels, or by a respective converter lamina per semiconductor chip. In both cases, during operation of a light emitting diode or a pixel adjacent converter regions also emit light concomitantly which leads to deviations from the sought luminance distribution in the target plane, for example, on the road. This optical crosstalk brings about a blurring of the desired light distribution. By way of example, when there is oncoming traffic, a sharp separation between illuminated and non-illuminated regions is desired which results in the road being optimally illuminated for the driver of the vehicle, while oncoming drivers are not dazzled. In a blurred light distribution, by contrast, wider dimming has to be carried out to not dazzle oncoming drivers.

Therefore, it could be helpful to provide a conversion element that prevents optical crosstalk. In known light sources with converter laminae, in particular in light sources on the basis of laser-activated remote phosphor (LARP) for projection applications, there is furthermore the problem of very high evolution of heat in the converter lamina. This adversely affects the lifetime of the system. A rotating wheel with a ring-shaped converter track is therefore used in known LARP systems.

Therefore, it could also be helpful to provide a conversion element that is able to dissipate heat efficiently. As a result, the temperature of the conversion element during operation can be reduced and the lifetime of the system can be lengthened; mechanically moved parts or active cooling can be dispensed with.

### SUMMARY

We provide a conversion element including a separating structure and a multiplicity of conversion regions, wherein each conversion region is at least partly enclosed by a part of the separating structure, and each conversion region converts electromagnetic primary radiation at least partly into a secondary radiation having a longer wavelength.

We also provide a headlight including a conversion element including a separating structure and a multiplicity of conversion regions, wherein each conversion region is at least partly enclosed by a part of the separating structure, and each conversion region converts electromagnetic primary radiation at least partly into a secondary radiation having a longer wavelength.

We further provide a lighting device including a conversion element including a separating structure and a multiplicity of conversion regions, wherein each conversion region is at least partly enclosed by a part of the separating structure, and each conversion region converts electromagnetic primary radiation at least partly into a secondary radiation having a longer wavelength, further including at least one laser light source at a distance from the conversion element.

We yet further provide a method of producing a conversion element including providing a multiplicity of stack elements, wherein a cross section of at least some of the stack elements in at least one sectional area perpendicular to a main extension plane of the respective stack element is substantially curve-shaped and runs alternately on both sides of a straight line of intersection between the sectional area and the main extension plane; applying a conversion material to two surfaces of at least some of the stack elements; stacking the multiplicity of stack elements along a normal direction running perpendicular to the main extension planes of the stack elements, connecting the multiplicity of stack elements such that a layer stack arises; and cutting the layer stack in parallel cutting planes.

We still further provide a conversion element including a separating structure and a multiplicity of conversion regions, wherein each conversion region is at least partly enclosed by a part of the separating structure, each conversion region converts electromagnetic primary radiation at least partly into a secondary radiation having a longer wavelength, and each part of the separating structure that partly or completely encloses a respective conversion region includes two partial elements fixed to one another.

### BRIEF DESCRIPTION OF THE DRAWINGS

FIG. 1 shows a schematic cross-sectional view of a known headlight device.

FIGS. 2a-2c show method steps in the production of a conversion element in accordance with one example.

FIG. 3 shows further method steps in the production of the conversion element in accordance with the example.

FIG. 4 shows a schematic cross-sectional view of a headlight device in accordance with one example.

FIG. 5 shows a schematic cross-sectional view of an LARP lighting system in accordance with one example.

### DETAILED DESCRIPTION

Our conversion element may comprise a separating structure and a multiplicity of conversion regions, wherein each conversion region is at least partly or completely enclosed by a part of the separating structure and, wherein each conversion region converts electromagnetic primary radiation at least partly into a secondary radiation having a longer wavelength. Preferably, the separating structure is nontransmissive to the primary radiation and/or to the secondary radiation. Preferably, all the conversion regions comprise an identical conversion material. By way of example, all the conversion regions can be filled with the same conversion material.

Each part of the separating structure that partly or completely encloses a respective conversion region may comprise two partial elements fixed to one another, for example, adhesively bonded and/or soldered and/or welded together and/or connected thermally under pressure by a bonding process. Preferably, the separating structure comprises a multiplicity of strip-shaped elements having a wavy profile fixed to one another, for example, adhesively bonded and/or soldered and/or welded together and/or connected thermally under pressure by a bonding process. The conversion regions are preferably formed in the region of indentations in the strip-shaped elements. Edges of the strip-shaped elements can have singulation traces.

The conversion element may be nontransmissive to the primary radiation and/or the secondary radiation in directions perpendicular to a preferred direction. Preferably, the conversion element extends substantially perpendicular to the preferred direction and is at least partly transmissive to the primary radiation and/or the secondary radiation in the preferred direction. Preferably, the separating structure extends substantially parallel to the preferred direction.

Hereinafter, planes perpendicular to the preferred direction are taken to mean those planes perpendicular to the preferred direction that lie at least partly within the conversion element. Preferably, in each plane perpendicular to the preferred direction each conversion region is at least partly enclosed by a part of the separating structure. Preferably, in each plane perpendicular to the preferred direction each conversion region is completely circumferentially enclosed by a part of the separating structure.

In each conversion region, the cross section perpendicular to the preferred direction may be constant along the preferred direction. That is to say that the cross section of the conversion regions in planes perpendicular to the preferred direction remains the same and does not vary along the preferred direction. In this way, a conversion element is provided having structures only in directions running perpendicular to the preferred direction. The cross section of the conversion regions perpendicular to the preferred direction can have the shape of a polygon, for example, the shape of a hexagon or a quadrilateral, in particular a trapezoid.

In a plane perpendicular to the preferred direction, the multiplicity of conversion regions may be arranged in a two-dimensional lattice. In particular, the conversion regions in all planes perpendicular to the preferred direction can be arranged in a two-dimensional lattice. The two-dimensional lattice can be in particular a hexagonal or rectangular, in particular square, lattice. The lattice constants of the regular two-dimensional lattice are preferably 0.01 mm to 1 mm, particularly preferably 0.05 mm to 0.2 mm.

The conversion regions may be spatially separated from one another. In particular, two respectively adjacent conversion regions are formed separately from one another and not in a continuous fashion.

The separating structure may comprise a multiplicity of separating walls and a separating wall is arranged between two adjacent conversion regions. Preferably, each of the multiplicity of separating walls extends along the preferred direction. In this way, conversion regions are provided whose cross section proceeds in a constant fashion along the preferred direction.

The multiplicity of conversion regions may be arranged on a reflective layer. In this case, the reflective layer can be integrally formed with the separating structure. Preferably, the reflective layer extends perpendicular to the preferred direction. The reflective layer can be a specularly reflective coating formed from a metal or a metal compound. However, it is also possible for the reflective layer to be diffusely reflective or a dielectric multilayer.

The separating structure may contain a metal or consist of a metal. The metal is preferably a customary high-temperature metal having a melting point that is not too low, for example, titanium or tungsten. As a result, a thermally loadable conversion element is provided in which the heat occurring during radiation conversion can be efficiently dissipated. The thermal resistance of the conversion element is reduced compared to known conversion elements. In particular, the thermal resistance of the conversion element is significantly lower than that of a corresponding conversion element without a separating structure.

The conversion element may be in the form of a lamina. The thickness of the lamina along the preferred direction is preferably 0.01 mm to 1 mm, particularly preferably 0.05 mm to 0.2 mm. The maximum dimensioning of the lamina perpendicular to the preferred direction is preferably 0.1 mm to 10 mm, particularly preferably 0.5 mm to 2 mm.

The conversion element may be arranged on a carrier. Preferably, the carrier is formed as a heat sink. In particular, the conversion element is in direct contact with the heat sink carrier. During operation, this enables good cooling of the conversion element such that no or only a small impediment of the conversion efficiency occurs. By way of example, the heat sink can be formed from Cu, Al or a light metal die-cast part containing Zn, Mg or Al.

The primary radiation may be unconverted and may have a wavelength of 440 nm to 460 nm, which is particularly suitable for excitation of YAG phosphors. Alternatively, the primary radiation can already be converted, wherein with radiation having a shorter wavelength, for example, with UV radiation or with radiation having a wavelength of 400 nm to 410 nm, a converter is excited which reemits in the visible blue range. In LARP systems, the (unconverted) primary radiation can be generated by a short-wave laser and have a wavelength of 300 nm to 450 nm, preferably 350 nm to 410 nm.

Mixed-colored radiation composed of the primary radiation and the secondary radiation may be emitted from the conversion regions during operation. By way of example, blue light can be converted at least partly into green and/or red and/or yellow light by the conversion element such that the conversion regions emit white light during operation. Optionally, only secondary radiation can be emitted from the conversion regions during operation.

The conversion element can be provided for use in a transmission mode. That is to say that, during operation, primary radiation is incident on one side of the conversion element and the secondary radiation generated by conversion and the unconverted primary radiation emerge on the opposite side of the conversion element. The use in the transmission mode can be advantageous particularly in applications in headlights.

Optionally, the conversion element can also be provided for use in a reflection mode. That is to say that, during operation, primary radiation is incident on a first side of the conversion element and the secondary radiation generated by conversion and the unconverted primary radiation also emerge on the first side of the conversion element. This can occur solely by reflection, scattering and conversion processes within the conversion element. Optionally, however, a reflector can also be arranged on the opposite side of the conversion element relative to the first side, which reflector reflects the primary radiation and/or the secondary radiation back into the conversion element. The reflector can optionally be an additional layer or integrally embodied with the separating structure. The use in reflection mode can be advantageous particularly in LARP applications.

In LARP applications, the surface area of the conversion element perpendicular to the preferred direction is preferably 0.1 mm² to 20 mm², particularly preferably 0.5 mm² to 2 mm². In applications in automotive headlights, the surface area of the conversion element perpendicular to the preferred direction is preferably 0.1 mm² to 10 mm², particularly preferably 0.5 mm² to 5 mm².

When the conversion element is used with a light source having a multiplicity of pixels, preferably one conversion region is assigned to a pixel. Optionally, a plurality of conversion regions can also be assigned to a pixel. The conversion element can be used with a light source having individually addressable pixels, preferably 10 to 10,000 pixels and particularly preferably 100 to 2,500 pixels. The conversion element can also be used, for example, in an automotive headlight with a multiplicity of light emitting diodes, for example, five to ten light emitting diodes, which can each comprise a multiplicity of pixels, preferably 10 to 10,000 pixels and particularly preferably 100 to 2,500 pixels.

We also provide a headlight comprising a conversion element as described above. Furthermore, we provide a lighting device comprising a conversion element as described above, wherein the lighting device furthermore comprises at least one laser light source which is at a distance from the conversion element. The at least one laser light source can be a laser diode or an arrangement of laser diodes. The lighting device can be an LARP device, in particular.

Moreover, we provide a method of producing a conversion element as described above, comprising the following method steps: providing a multiplicity of stack elements, wherein the cross section of at least some of the stack elements in at least one sectional area perpendicular to a main extension plane of the stack element is substantially curve-shaped and runs alternately on both sides of the straight line of intersection between the sectional area and the main extension plane; applying a conversion material to two surfaces of at least some of the stack elements; stacking the multiplicity of stack elements along a normal direction running perpendicular to the main extension planes of the stack elements; connecting the multiplicity of stack elements such that a layer stack arises; and cutting the layer stack in parallel cutting planes.

In this case, a curve-shaped cross section means a cross section that substantially follows a curve and whose extent perpendicular to the curve is considerably smaller than its extent along the curve. Preferably, the extent of the cross section perpendicular to the curve, that is to say the thickness of a stack element, is 0.01 mm to 0.2 mm, particularly preferably 0.02 mm to 0.05 mm. The thickness of a stack element should preferably be chosen to be thin enough that, first, the stack elements can easily be embossed and, second, the separating structure to be produced does not absorb too much radiation for which the conversion element to be produced is intended to be transmissive in its preferred direction.

In this case, a curve means any one-dimensional course; a curve is therefore not restricted to curved curves, but rather in particular also includes courses composed of straight line segments.

The fact that a curve-shaped cross section runs alternately on both sides of a straight line means that the curve which the cross section follows crosses the straight line repeatedly such that the curve comprises both a multiplicity of first parts running on a first side of the straight line and a multiplicity of second parts running on a second side of the straight line, wherein the first parts and the second parts alternate along the curve. By virtue of the fact that the cross section of a stack element in a sectional area perpendicular to the main extension plane is substantially curve-shaped and runs alternately on both sides of the straight line of intersection between the sectional area and the main extension plane, this therefore results in a wavy profile of the stack element (and thus also of parts of the separating structure to be produced). The wavy profile can be rounded or angular or edged.

The height of each stack element perpendicular to its main extension plane may be less than 10%, particularly preferably less than 5%, of its maximum extent in the main extension plane. The stack elements are thus substantially plate-shaped, but in their course can deviate from their main extension plane to a certain degree and follow a wavy contour. The height of a stack element perpendicular to its main extension plane is preferably 0.01 mm to 1 mm, particularly preferably 0.05 mm to 0.2 mm. The maximum extent of a stack element in its main extension plane is preferably 0.1 mm to 50 mm, particularly preferably 0.5 mm to 2 mm.

The cutting planes may be parallel to the normal direction. Preferably, the cutting planes run perpendicular to the preferred direction of the conversion element to be produced. The conversion material can be applied to the surfaces, for example, by sedimentation, electrophoresis, blade coating or jetting. The conversion material can be present as a paste, for example, as a suspension of dye grains in a liquid precursor, e.g. a silicone oil or some other silicone-based precursor. The precursor is preferably crosslinkable to advantageously increase the strength of the conversion material. By way of example, the precursor can be thermally crosslinked and become a rubberlike material in the process. Optionally, the conversion material can be present in the form of dye grains in a matrix composed of a silicone elastomer.

Furthermore, the conversion material can optionally be present as a slip for subsequent processing to form a ceramic. The slip is first stirred in a liquid and then allowed to dry. As a result, a slurrylike material is formed which can be precured, pressed, heated and sintered by known ceramic processes.

The conversion material may be cured or precured after application. Preferably, after application the conversion material is first only precured and is only cured after the connection of the stack elements. What is thereby achieved is that the conversion material is still soft during the connection of the stack elements such that unevennesses can be compensated for and the conversion material can join together without any gaps.

The conversion material preferably contains phosphors which can be embedded into a matrix material. The matrix material can provide for a good adhesion between the stack elements and the phosphors after application.

By way of example, at least one of the following materials is appropriate for the phosphors: garnets doped with rare earth metals, alkaline earth metal sulfides doped with rare earth metals, thiogallates doped with rare earth metals, aluminates doped with rare earth metals, orthosilicates doped with rare earth metals, chlorosilicates doped with rare earth metals, alkaline earth metal silicon nitrides doped with rare earth metals, oxynitrides doped with rare earth metals, aluminum oxynitrides doped with rare earth metals.

Preferably, the phosphors are formed from doped garnets such as Ce- or Tb-activated garnets such as YAG:Ce, TAG:Ce, TbYAG:Ce.

Indentations in the wavy profile of at least some of the stack elements may be filled by application of the conversion material. What is achieved thereby is that after application the stack elements have a substantially planar form and can thus advantageously combine with one another. Preferably, in regions in which the wavy profile has no indentation, no conversion material is applied, or the conversion material applied there is spread into the indentations such that after application of the conversion material in the regions in which the wavy profile has no indentation layer the stack elements are free of conversion material.

At least one of the stack elements may have the form of a planar plate. Preferably, in the method step of applying a conversion material, no conversion material is applied to the stack elements having the form of a planar plate. Rather, the latter serve to separate from one another by the conversion regions formed by conversion material applied to other stack elements. Preferably, stack elements having a wavy profile (as a result of which parts of the separating structure to be produced are also formed in a wavy fashion) and stack elements having the form of a planar plate alternate in the layer stack. As a result, in indentations having a trapezoidal cross section, for example, conversion regions having a trapezoidal cross section can be formed.

Adjacent stack elements may have indentations at mutually corresponding locations such that, when adjacent stack elements are connected, regions in which indentations were filled with conversion material become situated one on top of another and form continuous conversion regions. It can likewise be provided that adjacent stack elements have no indentations at mutually corresponding locations such that, when adjacent stack elements are connected, regions in which no conversion material was applied during filling of the indentations become situated one on top of another and the regions of the adjacent stack elements which are free of conversion material are connected to one another.

All the stack elements may have substantially the same shape. Preferably, the stack elements are arranged in two different orientations, wherein the two orientations preferably alternate along the normal direction. What can be achieved thereby is that indentations on different sides of the main extension planes of adjacent stack elements become situated one on top of another during stacking.

If the conversion material is applied by jetting, this can be implemented as an inkjet printing method in which a print head is moved over the stack elements and fills indentations in the stack elements with conversion material.

When applying the conversion material, care should be taken to ensure that the conversion material has no gaps, but rather is applied in a continuous and flush fashion. The thermal resistance of the conversion element is reduced as a result.

The separating structure may form a honeycomb or tubular structure. Parts of the separating structure act as shading diaphragms (baffles) that prevent lateral crosstalk of the radiation between different conversion regions. This takes place purely optically by virtue of the parts of the separating structure acting as mirrors or absorbers. Preferably, the parts of the separating structure are very thin compared to the conversion regions such that they ideally only serve to prevent the optical crosstalk without themselves being concomitantly imaged.

The method step of providing the stack elements may comprise a method step in which plate-shaped sheets composed of a high-temperature metal, for example, titanium or tungsten, are provided and brought to the shape described above, for example, by embossing. This can take place in a stamping method, for example, in which a sheet is introduced between two masters and is brought to the desired shape by pressing and heating.

The stack elements may be fixed to one another, for example, adhesively bonded and/or soldered. For adhesive bonding, for example, a silicone material can be used. Preferably, during connection of the stack elements, a thermal contact is produced between adjacent stack elements. A lower thermal resistance of the conversion element is achieved as a result. Adjacent stack elements can be point welded together by a laser process or connected thermally under pressure by a bonding process.

Conversion elements as described above are singulated by the method step of cutting the layer stack. The cutting therefore gives rise to conversion elements as described above having a laminar shape, wherein the conversion elements having a laminar shape extend substantially perpendicular to their preferred direction. The cutting is preferably carried out after the complete curing of the conversion material. The cutting can be carried out, for example, by sawing, optionally followed by grinding. The stack elements form the separating structures of the conversion elements.

Preferably 10 to 1,000, particularly preferably 50 to 200, stack elements are connected. Preferably, the layer stack is cut into 5 to 500, particularly preferably into 25 to 100, conversion elements.

In particular, the production method described above is suitable for production of the conversion element described above. Therefore, features described in association with the method can also be used for the conversion element and vice versa.

Further advantages and developments will become apparent from the examples described below in association with the figures.

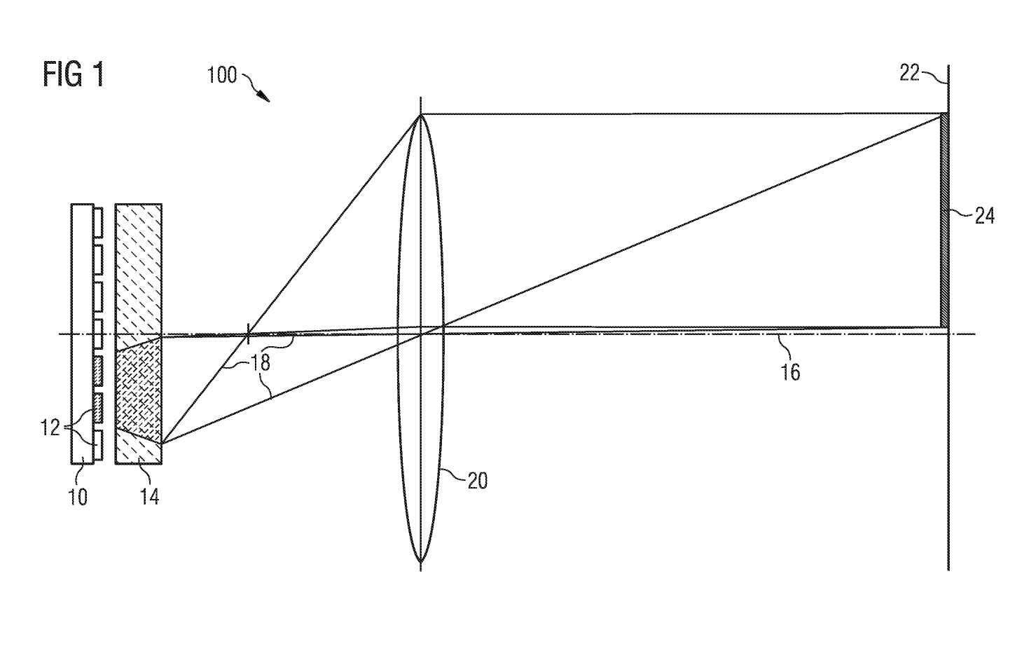

FIG. 1 shows a schematic cross-sectional view of a known headlight device, the headlight device being designated in its entirety by 100. The headlight device 100 comprises a light emitting device 10 comprising a multiplicity of light sources 12, for example, semiconductor chips, light emitting diodes or pixels. Here and hereinafter, a semiconductor chip can be, for example, a laser diode chip or a light emitting diode chip. The light sources 12 are arranged in a regular lattice. The light emitting device 10 can be, for example, a light emitting diode or semiconductor chip array or a pixelated semiconductor chip. During operation of the light emitting device 10, the light sources 12 can be driven such that selected light sources 12 emit primary light. In this example, the primary light is blue light.

The headlight device 100 furthermore comprises a known converter lamina 14, which serves as a conversion element. The converter lamina 14 is disposed downstream of the light emitting device 10 in the direction of an optical axis 16 and partly converts the primary light emitted by the light sources 12 into secondary light. Since the known converter lamina 14 has no separating structure, the luminous region of the converter lamina 14 also comprises regions that do not directly succeed the light sources 12 selected for emitting light. That is to say that optical crosstalk occurs in the converter lamina 14.

The light 18 emitted by the converter lamina 14, the light comprising both primary light transmitted without being converted by the converter lamina and secondary light generated in the converter lamina 14 by conversion, is directed onto a lighting plane 22, for example, the road by an optical system 20, for example, a lens system or a reflector. On account of the optical crosstalk in the converter lamina 14, the lighting pattern 24 in the lighting plane 22 is blurred compared to the lighting pattern sought.

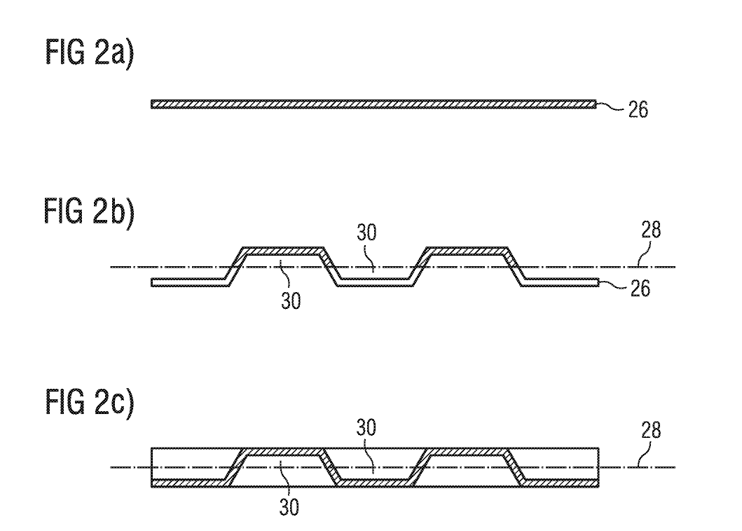

FIGS. 2a-2c show method steps in the production of a conversion element in accordance with one example. Thin planar sheets, for example, composed of titanium serve as starting material. One such sheet 26 is provided in a first method step 2a) and is shown in FIG. 2a in a cross-sectional view in a plane perpendicular to the main extension plane of the sheet.

In a next method step 2b) shown in FIG. 2b, the sheet 26 is structured in a wavy fashion. In this example, the sheet 26 is structured such that indentations 30 having a trapezoidal cross section alternately arise above and below the main extension plane 28 of the sheet 26. The cross section of the sheet 26 in the plane of the drawing perpendicular to the main extension plane 28 follows a curve composed of straight line segments and runs alternately on both sides of the straight line of intersection between the plane of the drawing and the main extension plane 28.

In a next method step 2c) shown in FIG. 2c, the indentations 30 are filled with conversion material, for example, by blade coating.

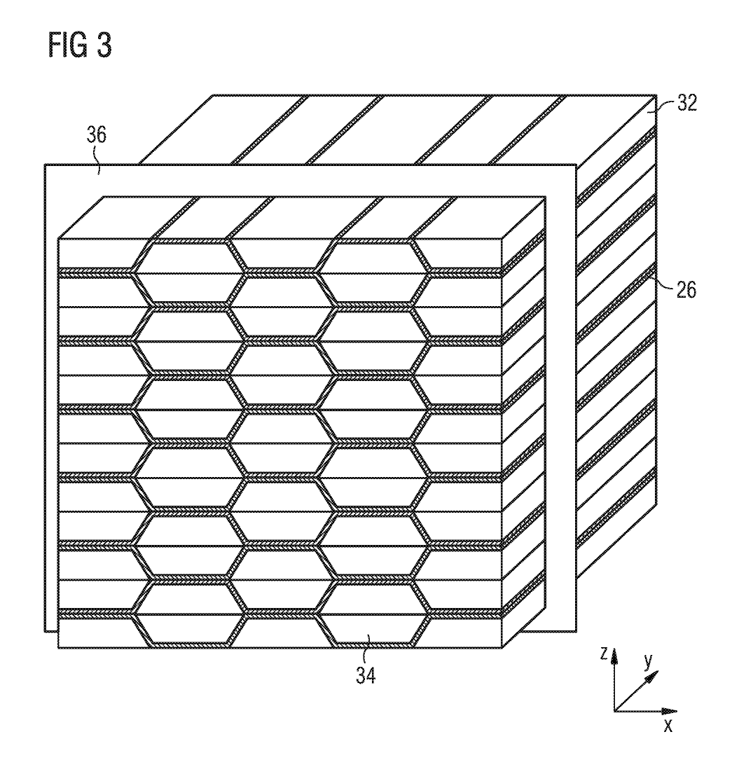

FIG. 3 shows further method steps in the production of the conversion element in accordance with the example. In one further method step, the sheets 26 structured in a wavy fashion together with the conversion material filled into the indentations 30 are stacked one on top of another along a normal direction z and subsequently connected to form a layer stack 32. In this example, the sheets 26 are stacked one on top of another such that regions in which the sheet 26 is exposed become situated one on top of another and regions in which indentations 30 were filled with conversion material become situated one on top of another. The sheets 26 all have substantially the same shape, but are arranged in two different orientations that alternate along the normal direction z. As a result, the regions filled with conversion material and having a trapezoidal cross section are combined to form conversion regions 34 having a hexagonal cross section, which in cross section are each completely enclosed by the sheets 26.

In a last method step, the resulting structure is divided along planes running parallel to the normal direction z, for example, by sawing. One such cutting plane is designated by 36 in FIG. 3. Individual plates serving as conversion elements are produced as a result. The preferred direction of the conversion elements is designated by y in FIG. 3. It is perpendicular to the cutting planes 36 and to the normal direction z. The conversion elements have a laminar shape and substantially extend in the normal direction z and a direction x perpendicular to the preferred direction y and the normal direction z.

In the conversion elements the sheets serve as separating walls forming a separating structure that is nontransmissive to the primary radiation which the conversion material is designed to convert, and to the secondary radiation which arises in the course of the conversion during operation. As a result, the conversion elements are nontransmissive to the primary radiation and secondary radiation in the x and z directions, but transmissive in the preferred direction y. In planes perpendicular to the preferred direction y, the conversion regions are each enclosed by the separating structure formed by the sheets. The cross section of the conversion regions perpendicular to the preferred direction y has the shape of a hexagon and is constant along the preferred direction y. On account of the regular arrangement of the sheets, the conversion regions in planes perpendicular to the preferred direction y are arranged in a hexagonal lattice.

Optionally, during stacking of the sheets, between respectively two sheets structured in a wavy fashion, a planar sheet can be inserted, that is to say a sheet for which method steps 2b) and 2c) were not performed. By virtue of these additional sheets, the trapezoidal regions filled with conversion material remain separated from one another such that trapezoidal conversion regions arise. Furthermore, examples having further shapes of the conversion regions, for example, having rectangular conversion regions, are also possible. Rounded shapes of the conversion regions are also possible, for example, shapes composed of semicircles or sinusoidal shapes. The shapes shown here having courses that are rectilinear in portions have the advantage, however, that planar bearing surfaces are available for the connection of the sheets.

In the example, the conversion elements are each structured only in the x and z directions and have substantially the same cross section everywhere along the preferred direction y. However, it is also possible for the conversion elements also to be structured along the preferred direction y.

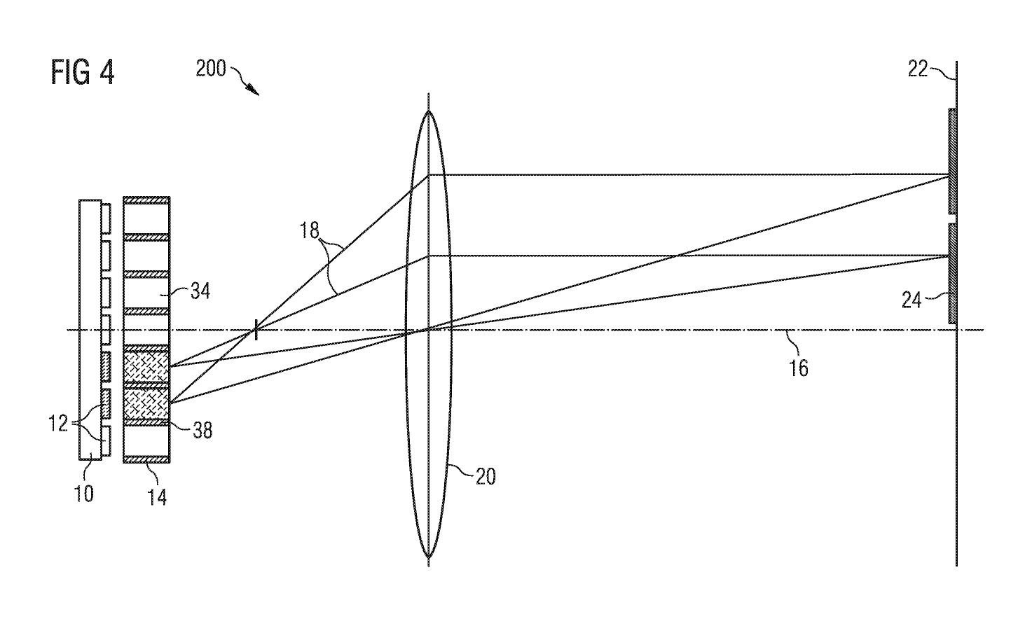

FIG. 4 shows a schematic cross-sectional view of a headlight device in accordance with one example, the headlight device being designated in its entirety by 200. The headlight device 200 has substantially the same construction as the known headlight device 100 as shown in FIG. 1. However, the converter lamina 14 now has a separating structure 38 and separated conversion regions 34. The converter lamina 14 is transmissive to the light 18 in a preferred direction corresponding to the direction of the optical axis 16. In directions perpendicular to that direction, by contrast, the light 18 is absorbed or reflected by the separating structure. As a result, the optical crosstalk in the converter lamina 14 is prevented and the lighting pattern 24 in the lighting plane 22 is clearly contoured and corresponds more precisely to the lighting pattern sought since it is not blurred.

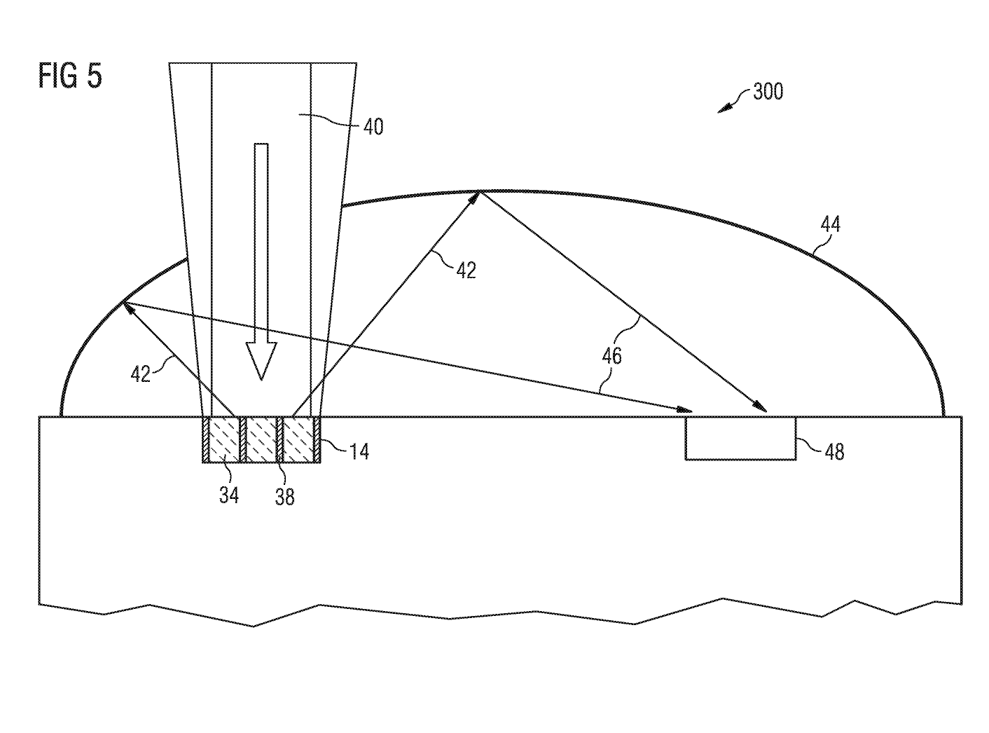

FIG. 5 shows a schematic cross-sectional view of an LARP lighting system in accordance with one example, the system being designated in its entirety by 300. In this lighting system, pump light 40 is incident on a converter lamina 14 having a separating structure 38 and separated conversion regions 34. The pump light 40 is focused onto the converter lamina 14. The pump light 40 can be, for example, blue laser light generated by a laser light source, for example, a laser diode. The pump light 40 is converted and reflected in the converter lamina 14. The converted light 42 impinges on a reflector 44 embodied in an elliptic fashion in this example. The reflector 44 transmits the pump light 40 and reflects the converted light 42. This can be realized, for example, by virtue of the reflector 44 having an opening for the pump light 40 or a suitable coating.

The light 46 reflected by the reflector 44 is focused onto an exit surface 48 such that a very high luminance is achieved at the exit surface 48. At this location, wavelength filtering can be carried out or an optical waveguide, for example, an optical fiber can be coupled thereto.

On account of the metallic separating structure, the converter lamina 14 is able to dissipate the heat occurring during the operation of the lighting system 300 more efficiently than a known converter lamina. As a result, the converter lamina 14 has a higher thermal loading capacity and mechanically moved parts or active cooling can be dispensed with.

Our elements and methods are not restricted to the examples by the description on the basis of the examples. Rather, this disclosure encompasses any novel feature and also any combination of features, which in particular includes any combination of features in the appended claims, even if the feature or combination itself is not explicitly specified in the claims or examples.

This patent application claims the priority of DE 102013107227.5, the disclosure of which is hereby incorporated by reference.

1.-15. (canceled)

16. A conversion element comprising a separating structure and a multiplicity of conversion regions, wherein each conversion region is at least partly enclosed by a part of the separating structure, and each conversion region converts electromagnetic primary radiation at least partly into a secondary radiation having a longer wavelength.

17. The conversion element according to claim 16, wherein the separating structure is nontransmissive to the primary radiation and/or to the secondary radiation.

18. The conversion element according to claim 16, wherein the conversion element is nontransmissive to the primary radiation and/or to the secondary radiation in directions perpendicular to a preferred direction.

19. The conversion element according to claim 18, wherein, in each plane perpendicular to the preferred direction, each conversion region is at least partly enclosed by a part of the separating structure.

20. The conversion element according to claim 18, wherein, in each conversion region, the cross section perpendicular to the preferred direction is constant along the preferred direction.

21. The conversion element according to claim 18, wherein the cross section of the conversion regions perpendicular to the preferred direction has a polygon shape.

22. The conversion element according to claim 18, wherein, in a plane perpendicular to the preferred direction, the conversion regions are arranged in a two-dimensional lattice.

23. The conversion element according to claim 16, wherein the separating structure comprises a multiplicity of separating walls and a separating wall is arranged between two adjacent conversion regions.

24. The conversion element according to claim 16, wherein the conversion regions are arranged on a reflective layer.

25. The conversion element according to claim 16, wherein the separating structure contains a metal or consists of a metal.

26. A headlight comprising a conversion element according to claim 16.

27. A lighting device comprising a conversion element according to claim 16, further comprising at least one laser light source at a distance from the conversion element.

28. A method of producing a conversion element comprising:
providing a multiplicity of stack elements, wherein a cross section of at least some of the stack elements in at least one sectional area perpendicular to a main extension plane of the respective stack element is substantially curve-shaped and runs alternately on both sides of a straight line of intersection between the sectional area and the main extension plane;
applying a conversion material to two surfaces of at least some of the stack elements;
stacking the multiplicity of stack elements along a normal direction running perpendicular to the main extension planes of the stack elements,
connecting the multiplicity of stack elements such that a layer stack arises; and
cutting the layer stack in parallel cutting planes.

29. The method according to claim 28, wherein a height of each stack element perpendicular to its main extension plane is less than 10% of its maximum extent in a main extension plane.

30. The method according to claim 28, wherein the cutting planes are parallel to a normal direction.

31. A conversion element comprising a separating structure and a multiplicity of conversion regions, wherein each conversion region is at least partly enclosed by a part of the separating structure, each conversion region converts electromagnetic primary radiation at least partly into a secondary radiation having a longer wavelength, and each part of the separating structure that partly or completely encloses a respective conversion region comprises two partial elements fixed to one another.

32. The conversion element according to claim 31, wherein the separating structure comprises a multiplicity of strip-shaped elements having a wavy profile, which are fixed to one another.
